(19) United States
(12) Patent Application Publication
(10) Pub. No.: US 2012/0012161 A1
(43) Pub. Date: Jan. 19, 2012

(54) METHOD FOR PRODUCING A SOLAR CELL MODULE, AND SOLAR CELL MODULE PRODUCED BY THE METHOD

(75) Inventor: Kwang-sok Lee, Gangwon-do (KR)

(73) Assignee: BESTROOM CO., LTD., Gangneung-si, Gangwon-do (KR)

(21) Appl. No.: 13/258,781

(22) PCT Filed: Mar. 23, 2010
(86) PCT No.: PCT/KR10/01786

§ 371 Date: Sep. 22, 2011

(30) Foreign Application Priority Data
Mar. 23, 2009 (KR) 10-2009-0024435

(51) Int. Cl. H01L 31/048; H01L 31/18

(52) U.S. Cl. 136/251; 438/66; 257/E31.117

(57) ABSTRACT

According to the present invention, a method for producing a solar cell module comprises the steps of: arraying at least one solar cell on the upper surface of a base substrate; stacking a transparent upper substrate onto the base substrate to cover the solar cell; injecting a radiation-curable liquid adhesive resin composition into the space formed between the base substrate and the upper substrate such that the space is filled with the composition; and hardening the radiation-curable liquid adhesive resin composition.

### TECHNICAL INVENTION

The present invention relates to a method of producing a solar cell module and, more particularly, to a method of producing a solar cell module, having improved base substrate adhesion and filling processes for the packaging of the solar cell module, and a solar cell module produced using the same.

### BACKGROUND ART

This application claims priority based on Korean Patent Application No. 10-2009-0024435 filed on Mar. 23, 2009, the entire disclosure of which is incorporated by reference herein.

In general, a plurality of solar cells used for solar cell generation is produced in the form of a module within a package according to the requirement characteristic of a cell capacity, etc.

FIG. 1 shows major elements of a conventional solar cell module. As shown in the figure, the solar cell module has a structure, including an upper substrate 10 and a lower substrate 11 configured to face each other, a plurality of solar cells 12 coupled in series or in parallel between the upper substrate 10 and the lower substrate 11 by means of conductive ribbons 13, a filler 14 filled between spaces between the upper substrate 10 and the lower substrate 11, a sealant 15 configured to seal the edges of the module, and a metallic coating 16 configured to surround the sealant 15.

A solar cell module is installed in the outside and used for a long period of time. Accordingly, it is very important to form a filler so that solar cells can be effectively protected from external environments, such as ultraviolet rays, a change in temperature, humidity, and a shock.

In order to form the filler, a conventional method of placing an Ethylene Vinyl Acetate (EVA) Film on the upper and lower faces of solar cells and melting the EVA film by applying heat of high temperature to a solar cell module within a vacuum chamber was widely used. In addition, the filler may include silicon resin, a Polyvinyl Butyral (PVB) film and so on.

Patent Documents related to the technique for forming the filler using the EVA film may include, for example, Korean Patent Registration No. 858475.

If the filler is formed using the EVA film, however, peroxides contained in the EVA filler are optically decomposed by means of ultraviolet rays when the solar cell module is disposed in the outside. Accordingly, there is a problem in that light transmittance is reduced because a yellowing phenomenon in which the filler is turned yellow is generated, and there is a danger of the penetration of moisture or the corrosion of electrodes. Furthermore, there are problems in that the EVA filler may be easily deteriorated by ultraviolet rays because it has a thermal insulation property, a product failure may be caused owing to excessive air bubbles generated in a high temperature process, and the solar cells of a thin film vulnerable to high pressure may be broken by pressure according to a vacuum process.

As an alternative, Korean Patent Registration No. 828262 discloses a process of manufacturing a solar cell module, including the process of coating epoxy adhesive resins on a top surface of the rear sheet unit of the solar cell module at specific intervals using a screen-printing method or a dispenser, the process of stacking an upper sheet glass unit over the rear sheet unit on which the epoxy adhesive resins are coated and then filling inert gas between the rear sheet unit and the upper sheet glass unit, the process of adhering the rear sheet unit and the upper sheet glass unit by curing the epoxy adhesives using a ultraviolet lamp.

According to Patent Registration No. 828262, the rear sheet unit and the upper sheet glass unit can be firmly adhered by means of the epoxy adhesive resin. This method, however, is problematic in that a work is inconvenient because it requires a process of coating an epoxy adhesive resin composition in the surroundings of the solar cells at specific intervals. Furthermore, there is a problem in that it is difficult to effectively protect the solar cells from an external mechanical shock or moisture because a resin filler is not provided between the rear sheet unit and the solar cells and between the upper sheet glass unit and the solar cells.

### DISCLOSURE

### Technical Problem

The present invention has been made in view of the above problems occurring in the prior art, and an object of the present invention is to provide a method of producing a solar cell module and a solar cell module produced using the same, which are capable of achieving an adhesion function between substrates and a function of protecting solar cells and the module itself by forming a resin filler in all empty spaces between a base substrate and an upper substrate, forming the solar cell module, without a high temperature process for melting the resin filler.

### Technical Solution

To achieve the above object, a method of producing a solar cell module according to the present invention includes the steps (a) arranging one or more solar cells over a base substrate; (b) stacking a transparent upper substrate over the base substrate in such way as to cover the solar cells; (c) filling a space between the base substrate and the upper substrate with a radiation-curable liquid adhesive resin composition by injecting the radiation-curable liquid adhesive resin composition; and (d) curing the radiation-curable liquid adhesive resin composition.

Preferably, the step (a) may further include the step of forming a spacer structure, interposable between the base substrate and the upper substrate, on the base substrate.

The spacer structure may be formed by attaching a double-sided tape along edges of the base substrate.

It is preferred that the double-sided tape be an acrylic foam double-sided tape.

Alternatively, the spacer structure may be formed by performing a silk screen printing process or a dispensing process along the edges of the base substrate.

It is preferred that a passage structure without the spacer structure be provided in at least part of the edges of the base substrate. Furthermore, it is preferred that the radiation-curable liquid adhesive resin composition be injected through an adhesive resin inlet provided by the passage structure and after the radiation-curable liquid adhesive resin composition is injected, the adhesive resin inlet be sealed.

It is preferred that at the step (c), a ultraviolet-curable liquid adhesive resin composition be used as the radiation-curable liquid adhesive resin composition and at the step (d), the curing process be performed by radiating ultraviolet rays through at least one of the upper substrate and the base substrate.

It is preferred that the radiation-curable liquid adhesive resin composition have a viscosity of 50 to 300 cps.

The step (c) may further include the step of removing air bubbles existing in the filler after filling the radiation-curable liquid adhesive resin composition.

According to another aspect of the present invention, there is provided as a solar cell module produced using the above method.

### Advantageous Effects

According to the present invention, the inside of a module can be filled to the utmost with resin because a filler is formed by injecting a liquid adhesive resin composition into the module and then curing the liquid adhesive resin composition.

Furthermore, damage to solar cells due to an external mechanical shock or moisture can be prevented because a resin filler firmly surrounds and protects the solar cells after a curing process.

Furthermore, reflectance for solar light can be reduced through the resin filler, and light of all wavelength bands can be fully absorbed. Accordingly, cell efficiency can be improved as compared with a case where the resin filler is not used.

### DESCRIPTION OF DRAWINGS

The following figures accompanied by this specification illustrate a preferred embodiment of the present invention and function to make understood the technical spirit of the present invention along with a detailed description of the invention. Accordingly, the present invention should not be interpreted as being limited to only the figures.

FIG. 1 is a cross-sectional view showing the construction of a conventional solar cell module.

FIG. 2 is a flowchart illustrating a process of performing a method of producing a solar cell module according to a preferred embodiment of the present invention.

FIG. 3 is a plan view showing a construction in which solar cells and a spacer structure are provided over the lower substrate of the solar cell module according to a preferred embodiment of the present invention.

FIG. 4 is a lateral view showing major elements of a curing system for performing a ultraviolet radiation-curable process.

FIG. 5 is a cross-sectional view showing the construction of the solar cell module produced according to a preferred embodiment of the present invention.

FIG. 6 is a graph showing measurement results of photoelectric conversion efficiency of the solar cell module in which a resin filler is formed according to a preferred embodiment of the present invention.

FIG. 7 is a graph showing measurement results of photoelectric conversion efficiency of a solar cell module without a resin filler according to the prior art.

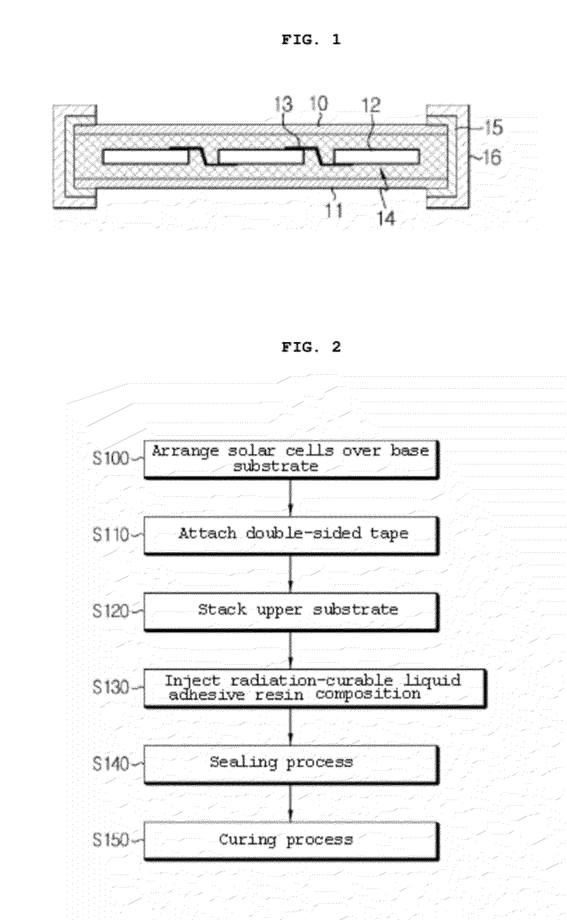

### MODE FOR INVENTION

Hereinafter, preferred embodiments of the present invention will be described in detail with reference to the accompanying drawings. Terms or words used in this specification and the claims should not be limitedly interpreted as having common or dictionary meanings, but should be interpreted as having meanings adapted to the technical spirit of the present invention on the basis of a principle that the inventor can appropriately define the concepts of the terms in order to describe his invention in the best way. Accordingly, the embodiments described in this specification and constructions shown in the drawings illustrate only the most preferred embodiments of the present invention and do not represent the entire technical spirit of the present invention. Accordingly, it should be understood that a variety of equivalent arrangements and modifications which may replace the embodiments and the constructions may exist at the time of filing of this application.

FIG. 2 is a flowchart illustrating a process of performing a method of producing a solar cell module according to a preferred embodiment of the present invention.

Referring to FIG. 2, a method of producing a solar cell module includes a solar cell arrangement process (step S100), a spacer structure formation process (step S110), an upper substrate stacking process (step S120), a liquid adhesive resin composition injection process (step S130), a sealing process (step S140), and a curing process (step 150).

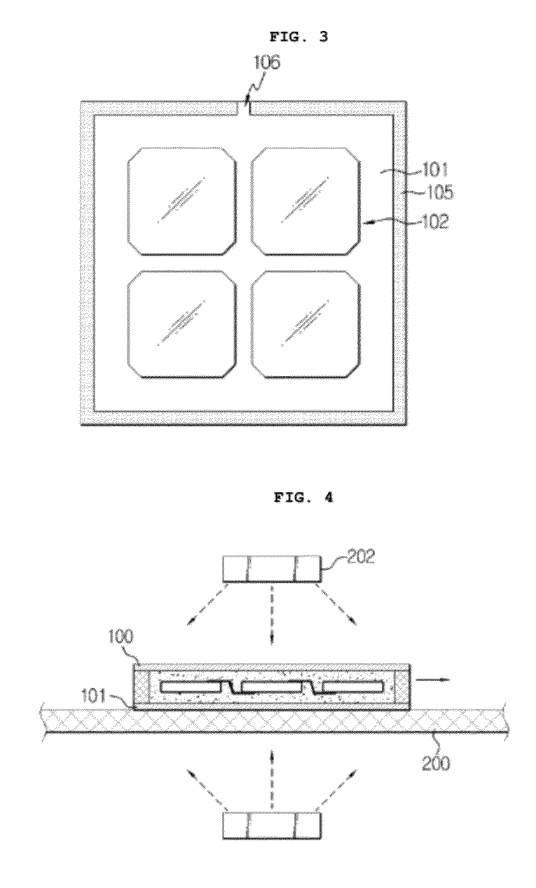

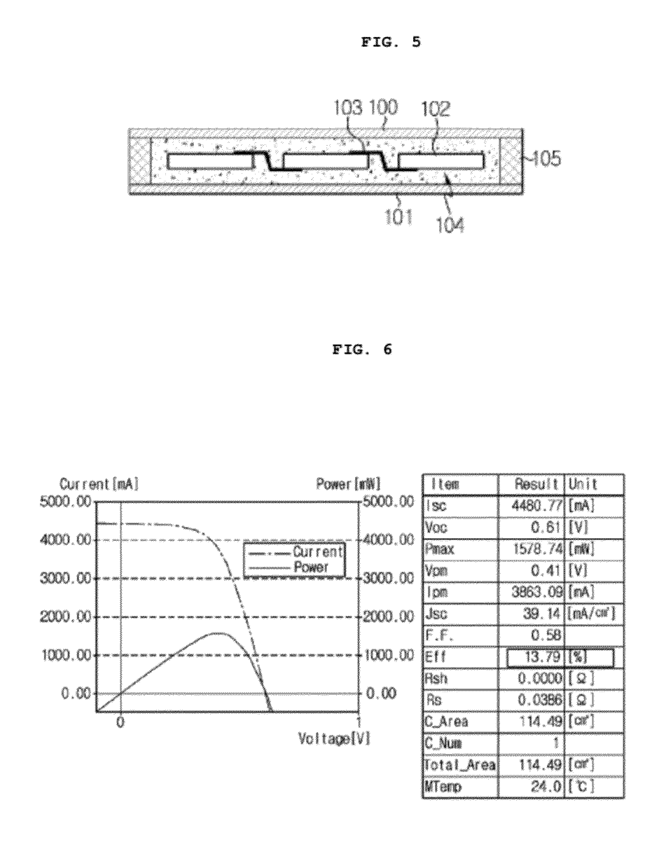

In the solar cell arrangement process (step S100), as shown in FIG. 3, the solar cells 102 are arranged over a base substrate 101. A glass sheet, a Polyethylene (PE) sheet, a Polyethyleneterephthalate (PET) sheet, a metal sheet or the like may be used as the base substrate 101. The solar cells 102 are coupled in series or in parallel by means of conductive ribbon (refer to 103 of FIG. 5), thus forming an assembly structure.

In the spacer structure formation process (step S110), a spacer structure 105 is fabricated on a top surface of the base substrate 101 by attaching a double-sided tape along the edges of the base substrate 101. Here, it is preferred that an acrylic foam double-sided tape be adopted as the double-sided tape.

As an alternative, the spacer structure 105 may also be formed by performing a silk screen printing process or a dispensing process at a specific thickness along the edges of the base substrate 101.

When an upper substrate (refer to 100 of FIG. 4) is stacked to cover the solar cells 102, the spacer structure 105 is interposed between the base substrate 101 and the upper substrate 100, thereby forming a space into which a liquid adhesive resin composition will be injected. In particular, if the spacer structure 105 is formed using the double-sided tape, subsequent processes, such as the injection of the adhesive resin composition, sealing, and curing, can be stably performed in the state in which the base substrate 101 and the upper substrate 100 are adhered and fixed together.

When the spacer structure 105 is formed, a passage structure 106 without the spacer structure 105 must be formed in at least part of the edges of the base substrate 101. When the upper substrate 100 is stacked, the passage structure 106 provides an adhesive resin inlet for injecting the liquid adhesive resin composition.

In the upper substrate stacking process (step S120), the transparent upper substrate 100 is stacked over the base substrate 101 so that the solar cells 102 are covered. A glass substrate, a PE sheet with high transmittance, or a PET sheet may be used as the upper substrate 100.

In the liquid adhesive resin composition injection process (step S130), the space between the base substrate 101 and the upper substrate 100 is filled by injecting a radiation-curable liquid adhesive resin composition through the adhesive resin inlet formed between the base substrate 101 and the upper substrate 100. In this process, the radiation-curable liquid adhesive resin composition fills the space between the base substrate 101 and the upper substrate 100 and also fills gaps between the base substrate 101 and the solar cells 102 and the upper substrate 100 and the solar cells 102 by means of a capillary phenomenon. In particular, it is preferred that the radiation-curable liquid adhesive resin composition have a viscosity of 50 to 300 cps so the gaps between the base substrate 101 and the solar cells 102 and the upper substrate 100 and the solar cells 102 can be smoothly filled and have a non-yellowing property. More preferably, the radiation-curable liquid adhesive resin composition may have a viscosity of 150 to 200 cps so that the gaps between the base substrate 101 and the solar cells 102 and the upper substrate 100 and the solar cells 102 can be smoothly filled.

A ultraviolet-curable liquid adhesive resin composition cured by the radiation of ultraviolet rays is used as the radiation-curable liquid adhesive resin composition. It is preferred that the radiation-curable liquid adhesive resin composition include a carbonyl group and one or more hydrogen donors and include a cycloalkyl compound having a carbon number of 3 to 10. The radiation-curable liquid adhesive resin composition constructed as above has a characteristic strong against the deterioration of ultraviolet rays. Here, the construction of the radiation-curable liquid adhesive resin composition used in the present invention is not limited to the above example.

Furthermore, it is preferred that benzyl dimethylketal be adopted as a photo initiator which is included in the radiation-curable liquid adhesive resin composition for a ultraviolet radical reaction, but the present invention is not limited to the example. A variety of photo initiators may also be adopted.

If the ultraviolet-curable liquid adhesive resin composition is used, there is an advantage in that the process can be simplified because ultraviolet rays can be radiated through the transparent upper substrate 100 or the base substrate 101. As an alternative, a liquid adhesive resin composition cured by the radiation of an e-beam, a visible ray, or infrared rays may be used as the radiation-curable liquid adhesive resin composition.

After the radiation-curable liquid adhesive resin composition is filled, it is preferred that a process of removing air bubbles existing in the filler using an injector or vacuum equipment be performed.

In the sealing process (step S140), the adhesive resin inlet is sealed using a sealant, such as silicon or epoxy, so that the injected liquid adhesive resin composition does not flow outside of the module.

In the curing process (step S150), as shown in FIG. 4, ultraviolet rays are radiated into the solar cell module through the upper substrate 100 and the base substrate 101 using ultraviolet lamps 202, thereby curing the radiation-curable liquid adhesive resin composition.

It is preferred that a curing system include a conveyer 200 configured to have a central portion opened or to have a transparent body formed at its central portion so that ultraviolet rays can pass therethrough and the ultraviolet lamps 202 placed on the lower and upper sides with the conveyer 200 interposed therebetween. In the curing process, the solar cell module for which the filling process has been completed is loaded on the conveyer 200, and the solar cell module passes through the upper and lower ultraviolet lamps 202, so that the liquid adhesive resin composition is cured by the radiation through the base substrate 101 and the upper substrate 100 of the solar cell module.

The radiation-curable liquid adhesive resin composition is cured in a solid or semi-solid state by means of the radiation of ultraviolet rays, thus forming a resin filler (refer to 104 of FIG. 5) which adheres the base substrate 101 and the upper substrate 100 together and fills the inside of the module.

Although not shown, after the curing process is completed, a process of testing characteristic of the solar cell module and a process of mounting a metallic coating on the corners of the solar cell module may be added.

FIG. 5 is a cross-sectional view showing the construction of the solar cell module produced according to a preferred embodiment of the present invention. As shown in the figure, the solar cell module include the upper substrate 100 and the base substrate 101 configured to face each other, the spacer structure 105 interposed between the upper substrate 100 and the base substrate 101 and configured to maintain the interval of the base substrate, the plurality of solar cells 102 coupled in series or in parallel by means of the conductive ribbons 103 between the upper substrate 100 and the base substrate 101, and the resin filler 104 filled between the upper substrate 100 and the base substrate 101.

In the resin filler 104 filled in the solar cell module, in particular, portions placed between the upper substrate 100 and the solar cells 102 functions to reduce reflectance for solar light in view of the characteristic of resin and to absorb light of all wavelength bands. Accordingly, there is an advantage of improving the photoelectric conversion efficiency of the solar cell, as compared with a case where the resin filler 104 is not used.

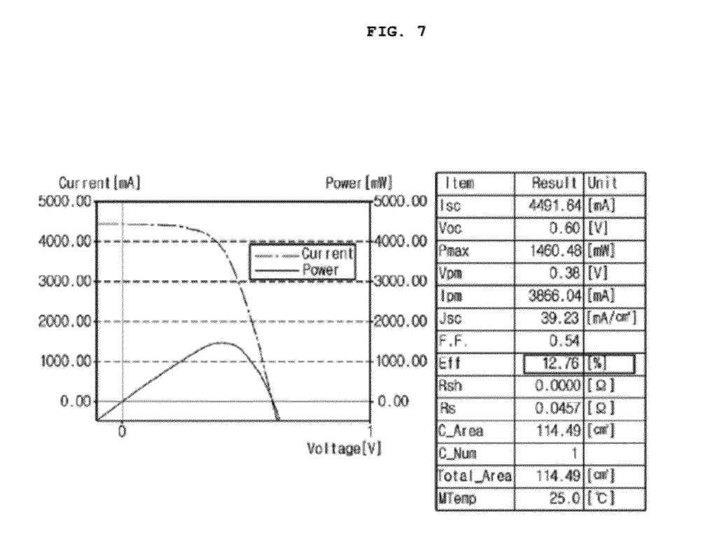

Actually, a case where the resin filler 104 is formed (refer to FIG. 6) and a case where the resin filler 104 is not formed (refer to FIG. 7), for specific solar cell module samples having the same specification of the solar cells 102, had 13.79% and 12.76%, respectively, in cell efficiency as a result of the comparison. It can be seen that the performance of the solar cell module is improved.

Although some exemplary embodiments of this document have been described above, this document is not limited to the above embodiments. It will be apparent to those skilled in the art that this document can be modified in various ways from the above description.

### INDUSTRIAL APPLICABILITY

If the present invention is used, the filler can be formed within the solar cell module using a low-temperature process, the process can be simplified, and the base substrate and the upper substrate can be adhered together over the entire area using uniform adhesion force.

Furthermore, according to the present invention, cell efficiency can be further improved because a reduction in light transmittance due to a yellowing phenomenon is not generated unlike in a conventional solar cell module including a resin filler formed of an EVA film.

Furthermore, according to the present invention, a double-sided tape can be used as a spacer for forming a space into which the liquid adhesive resin composition will be injected. Accordingly, the process of injecting the adhesive resin composition and the sealing and curing processes can be performed in the state in which the base substrate and the upper substrate are stably fixed.

1. A method of producing a solar cell module, comprising the steps of:
(a) arranging one or more solar cells over a base substrate;
(b) stacking a transparent upper substrate over the base substrate in such way as to cover the solar cells;
(c) filling a space between the base substrate and the upper substrate with a radiation-curable liquid adhesive resin composition by injecting the radiation-curable liquid adhesive resin composition; and
(d) curing the radiation-curable liquid adhesive resin composition.

2. The method according to claim 1, wherein the step (a) further comprises the step of forming a spacer structure, interposable between the base substrate and the upper substrate, on the base substrate.

3. The method according to claim 2, wherein at the step (a), the spacer structure is formed by attaching a double-sided tape along edges of the base substrate.

4. The method according to claim 3, wherein the double-sided tape is an acrylic foam double-sided tape.

5. The method according to claim 2, wherein at the step (a), the spacer structure is formed by performing a silk screen printing process or a dispensing process along the edges of the base substrate.

6. The method according to claim 1, wherein:
at the step (a), a passage structure without the spacer structure is provided in at least part of the edges of the base substrate,
at the step (c), the radiation-curable liquid adhesive resin composition is injected through an adhesive resin inlet provided by the passage structure, and
after the radiation-curable liquid adhesive resin composition is injected, the adhesive resin inlet is sealed.

7. The method according to claim 1, wherein:
at the step (c), a ultraviolet-curable liquid adhesive resin composition is used as the radiation-curable liquid adhesive resin composition, and
at the step (d), the curing process is performed by radiating ultraviolet rays through at least one of the upper substrate and the base substrate.

8. The method according to claim 7, wherein at the step (c), the radiation-curable liquid adhesive resin composition has a viscosity of 50 to 300 cps.

9. The method according to claim 7, wherein the radiation-curable liquid adhesive resin composition comprises a carbonyl group and one or more hydrogen donors and comprises a cycloalkyl compound having a carbon number of 3 to 10.

10. The method according to claim 9, wherein the radiation-curable liquid adhesive resin composition comprises benzil dimethylketal as a photo initiator.

11. The method according to claim 7, wherein the step (d) comprises the steps of:
preparing a curing system in which radiation devices are placed over and under a conveyer;
loading the solar cell module for which the filling process has been completed on the conveyer; and
operating the conveyer and the radiation devices to convey the solar cell module and simultaneously curing the radiation-curable liquid adhesive resin composition through the base substrate and the upper substrate of the solar cell module.

12. The method according to claim 1, wherein the step (c) further comprises the step of removing air bubbles existing in the filler after filling the radiation-curable liquid adhesive resin composition.

13. A solar cell module produced using a method according to claim 1.
